(19) United States
(12) Patent Application Publication
(10) Pub. No.: US 2025/0031339 A1
(43) Pub. Date: Jan. 23, 2025

(54) ENCLOSED IMMERSION LIQUID COOLING APPARATUS

(71) Applicant: Hebei Qinhuai Data Co., Limited., Zhangjiakou City (CN)

(72) Inventor: Binghua ZHANG, Zhangjiakou City (CN)

(21) Appl. No.: 18/776,017

(22) Filed: Jul. 17, 2024

(30) Foreign Application Priority Data
Jul. 20, 2023 (CN) 202310894611.4

(51) Int. Cl. H05K 7/20

(52) U.S. Cl. CPC H05K 7/20236

(57) ABSTRACT

The present disclosure discloses an enclosed immersion liquid cooling apparatus, specifically relates to the technical field of liquid cooling apparatus, and includes a bottom plate. Four symmetrically-distributed fixed columns are fixedly connected to the bottom plate, an outer side of each of the four fixed columns is slidably sleeved with a sliding column, a regulating mechanism is arranged on the sliding column, and a box body is fixedly connected to the sliding column.

### CROSS REFERENCE TO RELATED APPLICATION

This application claims priority to Chinese Patent Application No. 202310894611.4, titled “ENCLOSED IMMERSION LIQUID COOLING APPARATUS” and filed to the China National Intellectual Property Administration on Jul. 20, 2023, the entire contents of which are incorporated herein by reference.

### TECHNICAL FIELD

The present disclosure relates to the technical field of liquid cooling apparatus, and more particularly, to an enclosed immersion liquid cooling apparatus.

### BACKGROUND

With the advent of the information age, there are more and more high-speed and high computing electronic devices, such as commonly used personal computers, server rooms in enterprises, server computing centers rented by large companies, and even large computing centers that reflect national strength. As the integration level of the high-density computing devices increases, heat generation per unit volume increases exponentially, and immersion liquid cooling solutions are increasingly accepted and adopted by more and more users. According to the invention patent with patent authorization proclamation No. CN218998633U, an enclosed immersion liquid cooling apparatus is disclosed, including a cooling box and a cover plate. A middle part at a front end of the cooling box is provided with an observation window, and middle parts at left and right sides of the cooling box are both fixedly connected to a fan. A plurality of heat transfer plates are fixedly connected to a rear end of the cooling box equidistantly, and a rear end of each of the heat transfer plates is fixedly connected to a front end of a heat dissipation plate. Middle parts on left and right sides and middle parts on front and rear sides at an upper end of the cooling box are provided with clamp slots, and middle parts on front and rear sides and middle parts on left and right sides of the cover plate are provided with clamp blocks, where the clamp blocks are clamped to the clamp slots, respectively. In the present disclosure, first, a first rubber ring is clamped to a second groove, and a second rubber ring is clamped to a first groove, such that a joint between the cover plate and the cooling box is tighter. Second, a cooling liquid is injected into the cooling box through a liquid injection pipe. Finally, the cooling liquid is discharged through a liquid outlet pipe and a conveying pipe by controlling on or off of a valve. However, in existing technologies, when the cover plate in the liquid cooling apparatus seals the cooling box, the cover plate is fixed by bolts. When in use, vibration of the devices may occur, which may cause screws to rotate, thus having a negative effect on sealing performance of the liquid cooling apparatus. Moreover, it is not convenient for operators having different heights to observe through the observation window.

### SUMMARY

The present disclosure provides an enclosed immersion liquid cooling apparatus, aiming at solving a problem that a cover plate becomes loose due to vibration when the cover plate is fixed with bolts, and aiming to solve a problem that it is not convenient for operators having different heights to observe through an observation window.

Embodiments of the present disclosure provide an enclosed immersion liquid cooling apparatus, which includes a bottom plate, where four symmetrically-distributed fixed columns are fixedly connected to the bottom plate. An outer side of each of the four fixed columns is slidably sleeved with a sliding column, and a regulating mechanism is arranged on the sliding column. A box body is fixedly connected to the sliding column, a heat dissipation apparatus is arranged on the box body, an observation window is arranged on the box body, a conveying apparatus is arranged on the box body, and a sealing mechanism is arranged on the box body. Interior of the box body is slidably sleeved with a cover plate, which is fixedly connected to a liquid injection pipe.

In the enclosed immersion liquid cooling apparatus of the present disclosure, the sealing mechanism includes a sealing gasket, a positioning rod, a T-shaped rod, a first bevel gear, a second bevel gear, a clamp block, a first threaded rod, and a limit block. The positioning rod is fixedly connected to the box body, the positioning rod is slidably connected to the cover plate, and interior of the positioning rod is connected to the T-shaped rod through a bearing. The first bevel gear is fixedly connected to the T-shaped rod, the second bevel gear is meshed with the first bevel gear, interior of the second bevel gear is fixedly sleeved with the first threaded rod, and the first threaded rod is connected to the positioning rod through a bearing. The first threaded rod can be driven to rotate by rotating the T-shaped rod.

In the enclosed immersion liquid cooling apparatus of the present disclosure, an outer side of the first threaded rod is connected to the clamp block through a screw thread, where the clamp block is slidably connected to the positioning rod, and the clamp block is slidably connected to the cover plate. Rotation of the first threaded rod can drive the clamp block to move horizontally.

In the enclosed immersion liquid cooling apparatus of the present disclosure, two symmetrically-distributed limit blocks are fixedly connected to the clamp block, and each of the two limit blocks is slidably connected to the positioning rod. A movement distance of the clamp block can be limited by means of the limit blocks.

In the enclosed immersion liquid cooling apparatus of the present disclosure, an outer side of the positioning rod is slidably sleeved with the sealing gasket, where the sealing gasket is slidably connected to the box body, and the sealing gasket comes into contact with the cover plate. Sealing effects of the cover plate can be improved by means of the sealing gasket.

In the enclosed immersion liquid cooling apparatus of the present disclosure, the regulating mechanism includes a motor, a protective cover, a threaded sleeve, a second threaded rod, a connecting plate, and a cover plate. The motor is fixedly connected to the bottom plate, where an output end of the motor is fixedly connected to the second threaded rod, an outer side of the second threaded rod is connected to the threaded sleeve through a screw thread, and an outer side of the threaded sleeve is fixedly sleeved with the connecting plate, which is fixedly connected to the sliding column. By starting the motor, the sliding column and the box body can be driven to move vertically.

In the enclosed immersion liquid cooling apparatus of the present disclosure, an outer side of the motor is fixedly sleeved with the protective cover, where the protective cover is fixedly connected to the bottom plate, the protective cover comes into contact with the connecting plate, and the protective cover comes into contact with the threaded sleeve. The motor can be protected by means of the protective cover.

The technical solutions provided by the embodiments of the present disclosure may include following beneficial effects.

1. In the present disclosure, structures such as the T-shaped rod, the first threaded rod, the sealing gasket and the clamp block are arranged. Sealing performance of the cover plate can be increased by means of the sealing gasket. By rotating the T-shaped rod, the first threaded rod can be driven to rotate, and rotation of the first threaded rod can drive the clamp block to move horizontally. When the clamp block moves out of the positioning rod and comes into contact with the cover plate, the cover plate can be limited and fixed. When the clamp block moves and no longer comes into contact with the cover plate, the cover plate can be removed. Arrangement of the sealing mechanism increases stability of the cover plate during sealing and enhances stability of the liquid cooling apparatus during use.

2. In the present disclosure, structures such as the motor, the threaded sleeve, the second threaded rod and the connecting plate are arranged. The second threaded rod can be driven to rotate through an output end of the motor, and the rotation of the second threaded rod can drive the threaded sleeve and the connecting plate to move vertically. The vertical movement of the connecting plate can drive the sliding column, the observation window and the box body to move vertically, which facilitates adjustment of height of the observation window, making it convenient for operators having different heights to observe interior of the box body through the observation window. Furthermore, by arranging the regulating mechanism, convenience of using the liquid cooling apparatus is increased.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a three-dimensional view of an overall structure according to the present disclosure;

FIG. 2 is an elevation cross-sectional view of FIG. 1 according to the present disclosure; and

FIG. 3 is an enlarged view at Part A in FIG. 2 of the present disclosure.

### REFERENCE NUMERALS IN THE ACCOMPANYING DRAWINGS

bottom plate 1; fixed column 2; sliding column 3; conveying apparatus 4; box body 5; observation window 6; liquid injection pipe 7; sealing mechanism 8; sealing gasket 81; positioning rod 82; T-shaped rod 83; first bevel gear 84; second bevel gear 85; clamp block 86; first threaded rod 87; limit block 88; regulating mechanism 9; motor 91; protective cover 92; threaded sleeve 93; second threaded rod 94; connecting plate 95; cover plate 10; and heat dissipation apparatus 11.

### DETAILED DESCRIPTION

Technical solutions in the embodiments of the present disclosure will be described clearly and completely below, in conjunction with the accompanying drawings in the embodiments of the present disclosure. Apparently, the described embodiments are some but not all of the embodiments of the present disclosure. All other embodiments obtained by a person of ordinary skill in the art based on the embodiments of the present disclosure without creative efforts shall fall within the protection scope of the present disclosure.

It should also be understood that the terms used in this specification of the present disclosure are only for the purpose of describing particular embodiments and are not intended to limit the present disclosure. As used in the specification and the appended claims of the present disclosure, the singular forms of “a”, “an” and “the” may be intended to include the plural forms, unless the context clearly indicates otherwise.

It should also be further understood that the term “and/or” used in the specification and the appended claims of the present disclosure refers to any combination of one or more of the relevantly listed items and all possible combinations, and includes these combinations.

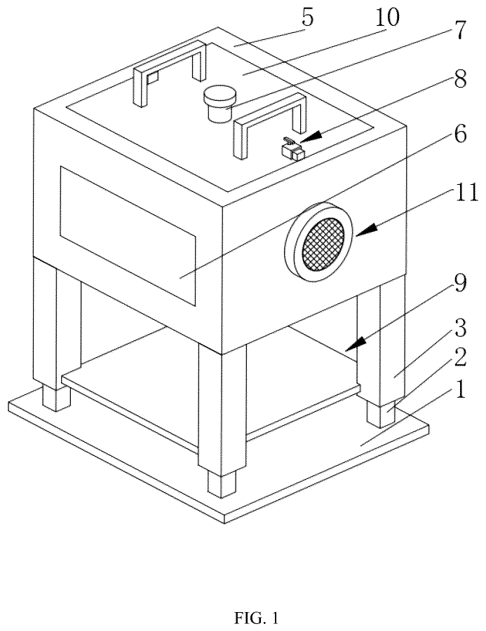

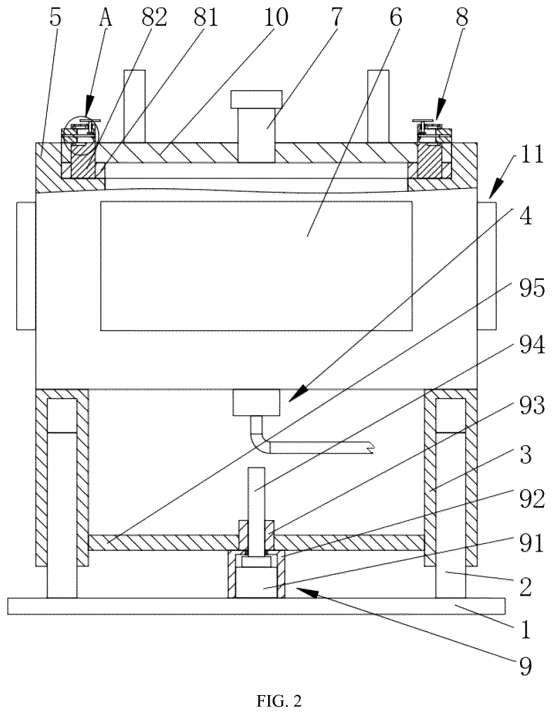

Referring to FIG. 1 and FIG. 2, an enclosed immersion liquid cooling apparatus includes a bottom plate 1, and four symmetrically-distributed fixed columns 2 are fixedly connected to the bottom plate 1. An outer side of each of the four fixed columns 2 is slidably sleeved with a sliding column 3, and a regulating mechanism 9 is arranged on the sliding column 3. A box body 5 is fixedly connected to the sliding column 3, a heat dissipation apparatus 11 is arranged on the box body 5, an observation window 6 is arranged on the box body 5, a conveying apparatus 4 is arranged on the box body 5, and a sealing mechanism 8 is arranged on the box body 5. Interior of the box body 5 is slidably sleeved with a cover plate 10, which is fixedly connected to a liquid injection pipe 7.

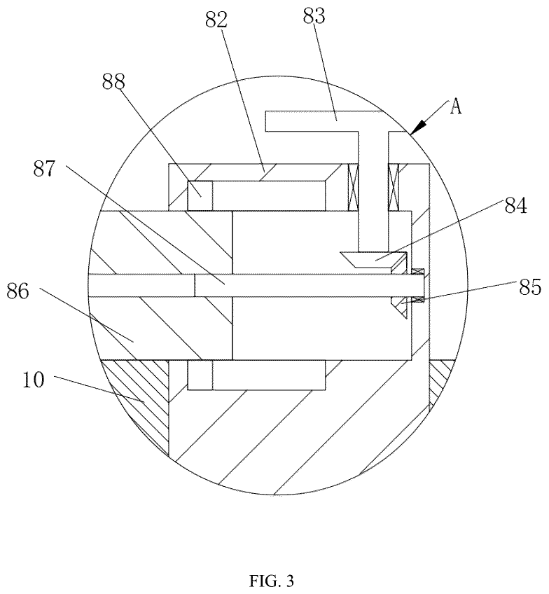

Referring to FIG. 2 and FIG. 3, the sealing mechanism 8 includes a sealing gasket 81, a positioning rod 82, a T-shaped rod 83, a first bevel gear 84, a second bevel gear 85, a clamp block 86, a first threaded rod 87, and a limit block 88. The positioning rod 82 is fixedly connected to the box body 5, the positioning rod 82 is slidably connected to the cover plate 10, and interior of the positioning rod 82 is connected to the T-shaped rod 83 through a bearing. The first bevel gear 84 is fixedly connected to the T-shaped rod 83, the second bevel gear 85 is meshed with the first bevel gear 84, interior of the second bevel gear 85 is fixedly sleeved with the first threaded rod 87, and the first threaded rod 87 is connected to the positioning rod 82 through a bearing. The first threaded rod 87 can be driven to rotate by rotating the T-shaped rod 83. An outer side of the first threaded rod 87 is connected to the clamp block 86 through a screw thread, where the clamp block 86 is slidably connected to the positioning rod 82, and the clamp block 86 is slidably connected to the cover plate 10. Rotation of the first threaded rod 87 can drive the clamp block 86 to move horizontally. Two symmetrically-distributed limit blocks 88 are fixedly connected to the clamp block 86, and each of the two limit blocks 88 is slidably connected to the positioning rod 82. A movement distance of the clamp block 86 can be limited by means of the limit blocks 88. An outer side of the positioning rod 82 is slidably sleeved with the sealing gasket 81, where the sealing gasket 81 is slidably connected to the box body 5, and the sealing gasket 81 comes into contact with the cover plate 10. Sealing effects of the cover plate 10 can be improved by means of the sealing gasket 81.

Referring to FIG. 2, the regulating mechanism 9 includes a motor 91, a protective cover 92, a threaded sleeve 93, a second threaded rod 94, a connecting plate 95, and a cover plate 10. The motor 91 is fixedly connected to the bottom plate 1, where an output end of the motor 91 is fixedly connected to the second threaded rod 94, an outer side of the second threaded rod 94 is connected to the threaded sleeve 93 through a screw thread, and an outer side of the threaded sleeve 93 is fixedly sleeved with the connecting plate 95, which is fixedly connected to the sliding column 3. By starting the motor 91, the sliding column 3 and the box body 5 can be driven to move vertically. An outer side of the motor 91 is fixedly sleeved with the protective cover 92, where the protective cover 92 is fixedly connected to the bottom plate 1, the protective cover 92 comes into contact with the connecting plate 95, and the protective cover 92 comes into contact with the threaded sleeve 93. The motor 91 can be protected by means of the protective cover 92.

Specific implementation processes of the present disclosure are as follows.

When in use, reference is made to the invention of the issued patent authorization proclamation No. CN211595669U for specific implementations of the enclosed immersion liquid cooling apparatus. When the cover plate 10 needs to be disassembled, the T-shaped rod 83 is rotated clockwise to drive the first bevel gear 84 to rotate. The rotation of the first bevel gear 84 can drive the second bevel gear 85 to rotate, and the rotation of the second bevel gear 85 can drive the first threaded rod 87 to rotate. Because the first threaded rod 87 is connected to the clamp block 86 through a screw thread, the rotation of the first threaded rod 87 can drive the clamp block 86 to perform threaded motion, which drives the clamp block 86 to move to a direction of the positioning rod 82. When the clamp block 86 moves and no longer comes into contact with the cover plate 10, the cover plate 10 is moved vertically such that the cover plate 10 no longer comes into contact with the positioning rod 82. In this way, the disassembly of the cover plate 10 is completed. When the cover plate 10 needs to be installed, the cover plate 10 is moved such that the positioning rod 82 is slidably inserted into the cover plate 10. When the cover plate 10 moves and comes into contact with the sealing gasket 81, it is continued to squeeze the cover plate 10. When the cover plate 10 moves to an appropriate position, the clamp block 86 is rotated counterclockwise to allow the clamp block 86 to move out of the positioning rod 82, such that the clamp block 86 comes into contact with both the positioning rod 82 and the cover plate 10. In this way, the cover plate 10 can be limited and fixed. Arrangement of the sealing mechanism 8 increases stability of the cover plate 10 during sealing and enhances stability of the liquid cooling apparatus during use. When it is required to adjust the height of the observation window 6, the motor 91 is started, and the second threaded rod 94 is driven to rotate through the output end of the motor 91. Because the second threaded rod 94 is connected to the threaded sleeve 93 through a screw thread, the rotation of the second threaded rod 94 can drive the threaded sleeve 93 to perform threaded motion, allowing the threaded sleeve 93 to move vertically. The movement of the threaded sleeve 93 can drive the connecting plate 95 to move, the movement of the connecting plate 95 can drive the sliding column 3 to move, and the movement of the sliding column 3 can drive the box body 5 to move. The height of the observation window 6 can be adjusted by the movement of the box body 5, making it convenient for operators having different heights to observe interior of the box body 5 through the observation window 6. Furthermore, by arranging the regulating mechanism 9, convenience of using the liquid cooling apparatus is increased.

The preceding descriptions are merely specific implementations of the present disclosure, but are not intended to limit the protection scope of the present disclosure. Any equivalent modifications or replacements easily conceivable to a person of skilled in the art within the technical scope disclosed in the present disclosure shall fall within the protection scope of the present disclosure. Therefore, the protection scope of the present disclosure shall be subject to that of the claims.

What is claimed is:

1. An enclosed immersion liquid cooling apparatus comprising a bottom plate, wherein four symmetrically-distributed fixed columns are fixedly connected to the bottom plate, an outer side of each of the four fixed columns is slidably sleeved with a sliding column, a regulating mechanism is arranged on the sliding column, a box body is fixedly connected to the sliding column, a heat dissipation apparatus is arranged on the box body, an observation window is arranged on the box body, a conveying apparatus is arranged on the box body, a sealing mechanism is arranged on the box body, interior of the box body is slidably sleeved with a cover plate, and the cover plate is fixedly connected to a liquid injection pipe.

2. The enclosed immersion liquid cooling apparatus according to claim 1, wherein the sealing mechanism comprises a sealing gasket, a positioning rod, a T-shaped rod, a first bevel gear, a second bevel gear, a clamp block, a first threaded rod, and a limit block; the positioning rod is fixedly connected to the box body, the positioning rod is slidably connected to the cover plate, interior of the positioning rod is connected to the T-shaped rod through a bearing, the first bevel gear is fixedly connected to the T-shaped rod, the second bevel gear is meshed with the first bevel gear, interior of the second bevel gear is fixedly sleeved with the first threaded rod, and the first threaded rod is connected to the positioning rod through a bearing.

3. The enclosed immersion liquid cooling apparatus according to claim 2, wherein an outer side of the first threaded rod is connected to the clamp block through a screw thread, the clamp block is slidably connected to the positioning rod, and the clamp block is slidably connected to the cover plate.

4. The enclosed immersion liquid cooling apparatus according to claim 2, wherein two symmetrically-distributed limit blocks are fixedly connected to the clamp block, and each of the two limit blocks is slidably connected to the positioning rod.

5. The enclosed immersion liquid cooling apparatus according to claim 2, wherein an outer side of the positioning rod is slidably sleeved with the sealing gasket, the sealing gasket is slidably connected to the box body, and the sealing gasket comes into contact with the cover plate.

6. The enclosed immersion liquid cooling apparatus according to claim 1, wherein the regulating mechanism comprises a motor, a protective cover, a threaded sleeve, a second threaded rod, a connecting plate, and a cover plate; the motor is fixedly connected to the bottom plate, an output end of the motor is fixedly connected to the second threaded rod, an outer side of the second threaded rod is connected to the threaded sleeve through a screw thread, an outer side of the threaded sleeve is fixedly sleeved with the connecting plate, and the connecting plate is fixedly connected to the sliding column.

7. The enclosed immersion liquid cooling apparatus according to claim 6, wherein an outer side of the motor is fixedly sleeved with the protective cover, the protective cover is fixedly connected to the bottom plate, the protective cover comes into contact with the connecting plate, and the protective cover comes into contact with the threaded sleeve.
